(19) United States
(12) Patent Application Publication
(10) Pub. No.: US 2025/0336720 A1
(43) Pub. Date: Oct. 30, 2025

(54) Integrated Circuit Package and Method

(71) Applicant: Taiwan Semiconductor Manufacturing Co., Ltd., Hsinchu (TW)

(72) Inventors: Hsin-Feng CHEN, Yilan (TW); Ke-Gang WEN, Hsinchu (TW); Tsung-Chieh HSIAO, Changhua (TW); Liang-Wei WANG, Hsinchu (TW); Yu-Bey WU, Hsinchu (TW)

(21) Appl. No.: 18/407,942

(22) Filed: Jan. 9, 2024

(51) Int. Cl. H01L 21/768; H01L 23/00; H01L 23/48; H01L 23/58

(52) U.S. Cl. CPC H01L 21/76831; H01L 21/76898; H01L 23/481; H01L 23/585; H01L 24/08; H01L 24/80; H01L 2224/08145; H01L 2224/80895; H01L 2224/80896

(57) ABSTRACT

A method of manufacturing a semiconductor device includes forming a first wafer, where forming the first wafer includes forming a plurality of first dielectric layers over a semiconductor substrate, depositing a second dielectric layer over the plurality of first dielectric layers, forming a first opening that extends through the second dielectric layer, the plurality of first dielectric layers, and partially through the semiconductor substrate, filling the first opening with a first Bottom Anti-Reflective Coating (BARC) layer, etching portions of the first BARC layer and the second dielectric layer to form a second opening, where the second opening overlaps and exposes a remaining portion of the first BARC layer in a remaining portion of the first opening, removing the first BARC layer, and concurrently forming a first through substrate via (TSV) in the remaining portion of the first opening and a first conductive pad in the second opening.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 illustrate cross-sectional views of intermediate steps during a process for forming semiconductor dies in accordance with some embodiments.

FIGS. 3 through 11A illustrate cross-sectional views of intermediate steps during a process for forming a semiconductor wafer in accordance with some embodiments.

FIG. 11B illustrates a cross-sectional view of intermediate steps during a process for forming the semiconductor wafer in accordance with other embodiments.

FIG. 12 illustrates a cross-sectional view of intermediate steps during a process for forming the semiconductor wafer in accordance with some embodiments.

FIGS. 13A through 16 illustrate cross-sectional views of intermediate steps during a process for forming an integrated chip package in accordance with some embodiments.

FIGS. 17 through 19 illustrate cross-sectional views of intermediate steps during a process for forming an integrated chip package in accordance with other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods applied to forming a through-substrate via (TSV) that extends through a bottom semiconductor device (e.g., a bottom die). A top semiconductor device (e.g., a top die) is then bonded to the bottom semiconductor device (e.g., the bottom die) to form a vertical stack in order to provide a 3D integrated chip (3DIC) package, such as a system on integrated chip (SoIC) package. The TSV may be used for signal or power transmission between the bottom semiconductor device and the top semiconductor device. The TSV may be formed to extend through a semiconductor substrate of the bottom semiconductor device and may also extend through a portion of an interconnect structure that is formed over the semiconductor substrate. A first metallization layer (e.g., including conductive wirings, a conductive pad, or the like) is formed concurrently with the TSV and is disposed within the interconnect structure, such that the processes that are used to form the TSV are also used to form the first metallization layer. The first metallization layer and the TSV may comprise similar materials, and may be in physical contact with each other, wherein the first metallization layer is used to electrically connect the TSV to other metallization layers disposed in the interconnect structure, external devices, or other dies. Advantageous features of one or more embodiments disclosed herein may allow the TSV and the first metallization layer to be formed at the same time, such that the processes used to form the TSV are also used to form the first metallization layer. This allows a reduction in the number of process steps (e.g., including metal plating and planarization steps) that are needed to form the TSV and the first metallization layer, as compared to the number of process steps that would be needed to be performed if the TSV and the first metallization layer were to be formed at different times using separate processes. As a result, manufacturing costs can be significantly reduced. In addition, concurrently forming the TSV and the first metallization layer using the same processes allows for the TSV and the first metallization layer to be in physical contact, without a barrier layer being disposed between the TSV and the first metallization layer. As a result, the resistivity between the TSV and the first metallization layer is reduced, allowing for more efficient electrical conduction, enhanced device performance, and reduced power consumption.

Embodiments will be described with respect to a specific context, namely the formation of a through substrate via (TSV) that is applied to a system on integrated chip (SoIC) package. However, other embodiments may also be applied to other packages, including Chip-on-Wafer-on-Substrate (CoWoS®) packages or integrated fan-out (InFO) packages. Embodiments discussed herein are to provide examples to enable making or using the subject matter of this disclosure, and a person having ordinary skill in the art will readily understand modifications that can be made while remaining within contemplated scopes of different embodiments. Like reference numbers and characters in the figures below refer to like components. Although method embodiments may be discussed as being performed in a particular order, other method embodiments may be performed in any logical order.

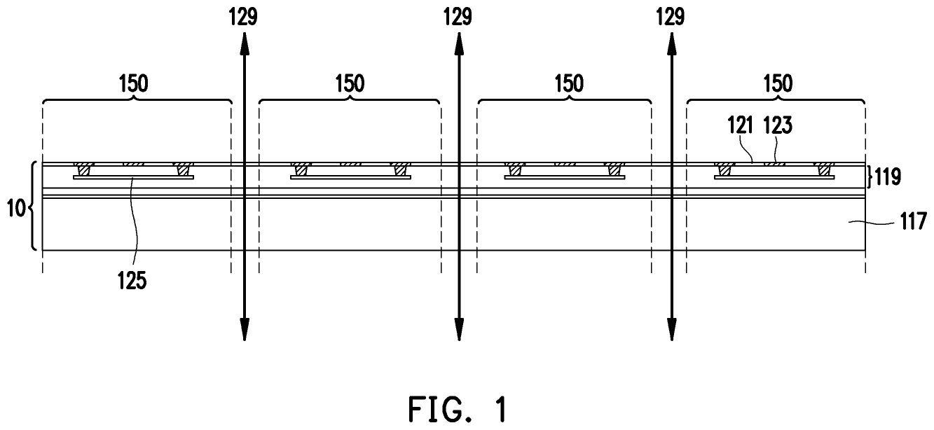

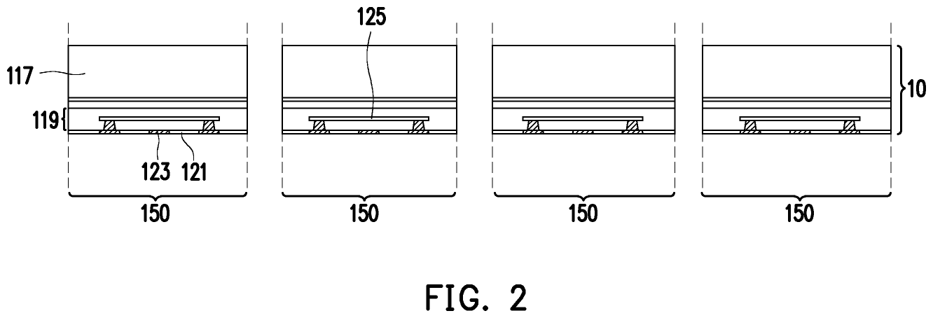

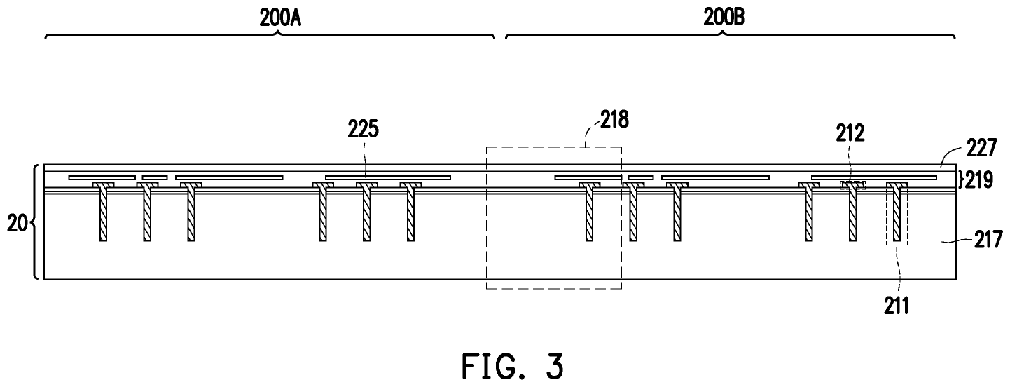

FIGS. 1 through 16 illustrate cross-sectional views of intermediate steps during a process for forming an integrated chip package 100, in accordance with some embodiments. FIGS. 1 and 2 illustrate cross-sectional views of intermediate steps during a process for forming semiconductor dies 150 in accordance with some embodiments. The semiconductor dies 150 (also referred to as top dies) will subsequently be bonded to a wafer 20 (also referred to as a bottom die). The wafer 20 is described further in FIGS. 3 through 12. In FIG. 1, a wafer 10 is illustrated. The wafer 10 comprises the semiconductor dies 150. Each of the semiconductor dies 150 may be a logic die (e.g., application processor (AP), central processing unit, microcontroller, etc.), a memory die (e.g., dynamic random access memory (DRAM) die, hybrid memory cube (HBC), a static random access memory (SRAM) die, a wide input/output (wideIO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like. Each semiconductor die 150 may also be a System-on-Chip (SoC) die, or the like. The wafer 10 may include a substrate 117 (e.g., a semiconductor substrate), an interconnect structure 119 disposed on the substrate 117, a bonding layer 121 disposed on the interconnect structure 119, and bonding pads 123 disposed in the bonding layer 121 and exposed at the front surface of the wafer 10.

The substrate 117 of the wafer 10 may include a crystalline silicon wafer. The substrate 117 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 117 may comprise an active layer of a semiconductor-on-insulator (SOI) substrate. The substrate 117 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Active and/or passive devices, such as transistors, diodes, capacitors, resistors, etc., may be formed in and/or on the substrate 117. The devices may be interconnected by the interconnect structure 119. The interconnect structure 119 electrically connects the devices on the substrate 117 to form one or more integrated circuits. The interconnect structure 119 may include one or more dielectric layers (for example, one or more interlayer dielectric (ILD) layers, intermetal dielectric (IMD) layers, or the like) and metallization patterns 125 (which may also be referred to subsequently as interconnect wirings) embedded in the one or more dielectric layers. The material of the one or more dielectric layers may include silicon oxide (SiOₓ, where x>0), silicon nitride (SiNₓ, where x>0), silicon oxynitride (SiOₓN_{y}, where x>0 and y>0), or other suitable dielectric material. The metallization patterns 125 may include metallic wirings. For example, the metallization patterns 125 include copper wirings, copper pads, aluminum pads or combinations thereof that are formed by one or more single damascene processes, dual damascene processes, or the like.

The bonding layer 121 may comprise a dielectric layer. Bonding pads 123 are embedded in the bonding layer 121, and the bonding pads 123 allow connections to be made to the interconnect structure 119 and the devices on the substrate 117. The material of the bonding layer 121 may be silicon oxide (SiOₓ, where x>0), silicon nitride (SiNₓ, where x>0), silicon oxynitride (SiOₓN_{y}, where x>0 and y>0), tetraethyl orthosilicate (TEOS), or other suitable dielectric material, and the bonding pads 123 may comprise conductive pads (e.g., copper pads), conductive vias (e.g., copper vias), or combinations thereof. The bonding layer 121 may be formed by depositing a dielectric material over the interconnect structure 119 using a chemical vapor deposition (CVD) process (e.g., a plasma enhanced CVD process or other suitable process); patterning the dielectric material to form the bonding layer 121 including openings or through holes; and filling conductive material in the openings or through holes defined in the bonding layer 121 to form the bonding pads 123 embedded in the bonding layer 121. In various embodiments, the back side of the wafer 10 may refer to a side of the wafer 10 on which a surface of the substrate 117 is exposed, and the front side of the wafer 10 may refer to a side of the wafer 10 on which the devices and the interconnect structure 119 are disposed.

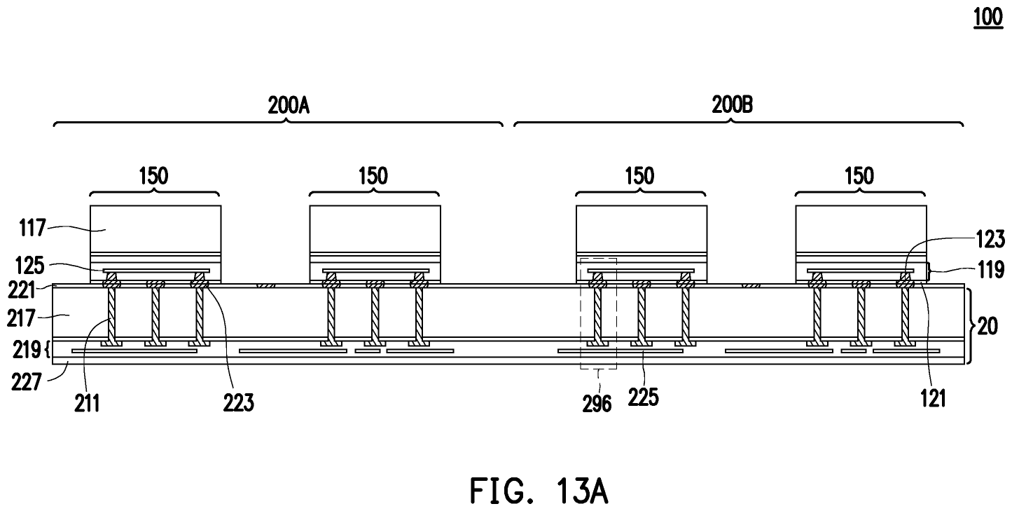

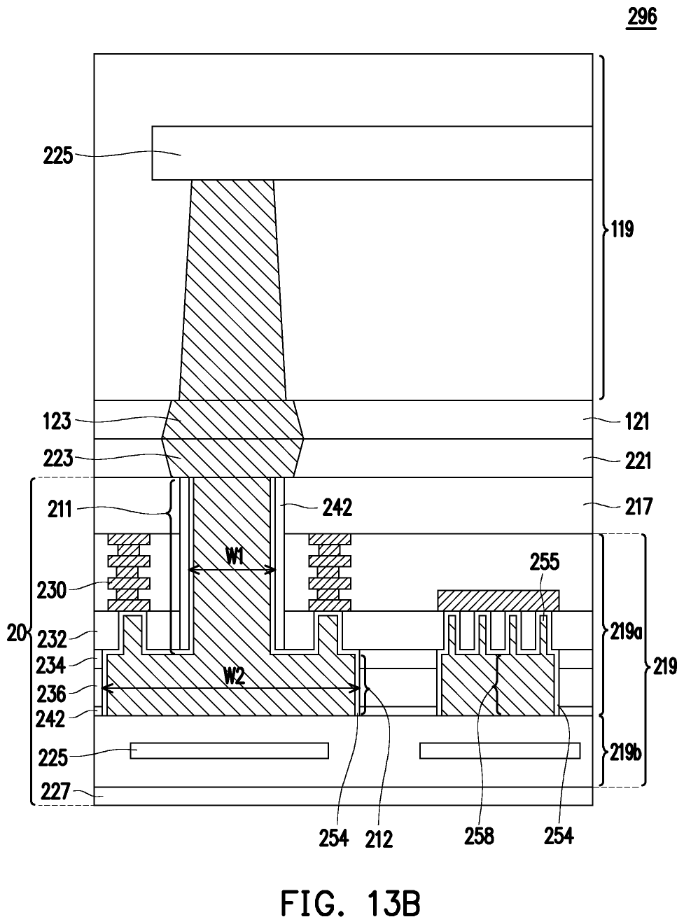

In FIG. 2, a dicing process is performed along dicing paths 129 that are shown in FIG. 1. The dicing process singulates the semiconductor dies 150 from each other along the dicing paths 129. Each of the dicing paths 129 is disposed between adjacent semiconductor dies 150. The dicing process may comprise, for example, a blade dicing process using an abrasive disc or blade saw rotating at high speed to cut along each dicing path 129. The blade tip may comprise abrasive grit or a thin diamond layer. The semiconductor dies 150 (also referred to as top dies) will subsequently be bonded to the wafer 20 (also referred to as a bottom die) as shown in FIGS. 13A-13B. The wafer 20 is described in more detail in FIGS. 3-12 below.

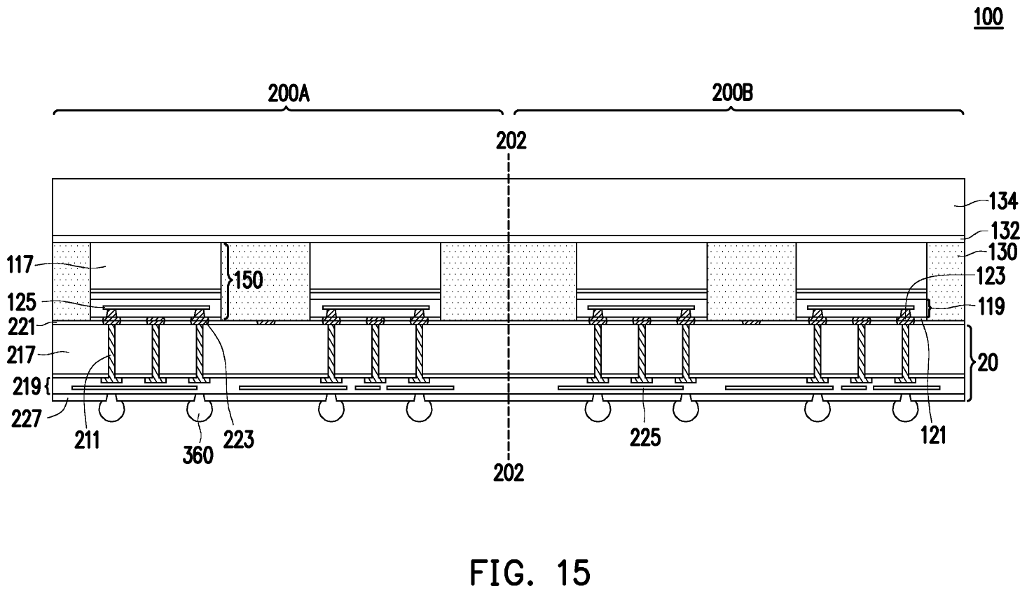

FIG. 3 illustrates the semiconductor wafer 20. The wafer 20 may also be subsequently referred to as a bottom die. The wafer 20 comprises a first package region 200A and a second package region 200B, and one or more of the integrated chip package 100 are packaged (e.g., as shown subsequently in FIG. 15) to form an integrated circuit package in each of the package regions 200A and 200B. The materials and formation processes of the features in the wafer 20 may be found by referring to the like features in the wafer 10, with the like features in the wafer 10 starting with number “1,” which features correspond to the features in the wafer 20 and having reference numerals starting with number “2.” For example, the wafer 20 may include a substrate 217 having devices (e.g., transistors, capacitors, diodes, resistors, or the like) formed thereon and an interconnect structure 219. The interconnect structure 219 electrically connects the devices on the substrate 217 to form one or more integrated circuits. The interconnect structure 219 includes one or more dielectric layers (for example, one or more interlayer dielectric (ILD) layers, intermetal dielectric (IMD) layers, or the like) and metallization patterns 225 (which may also be referred to subsequently as interconnect wirings) embedded in the one or more dielectric layers.

The wafer 20 may comprise a dielectric layer 227 that is formed over the interconnect structure 219. The dielectric layer 227 may comprise silicon oxide, silicon nitride, silicon carbide, silicon oxynitride, Spin-On-Polymers, silicon carbon material, compounds thereof, composites thereof, combinations thereof, or the like. The dielectric layer 227 may be deposited by any suitable method, such as, CVD, PECVD, spinning, or the like.

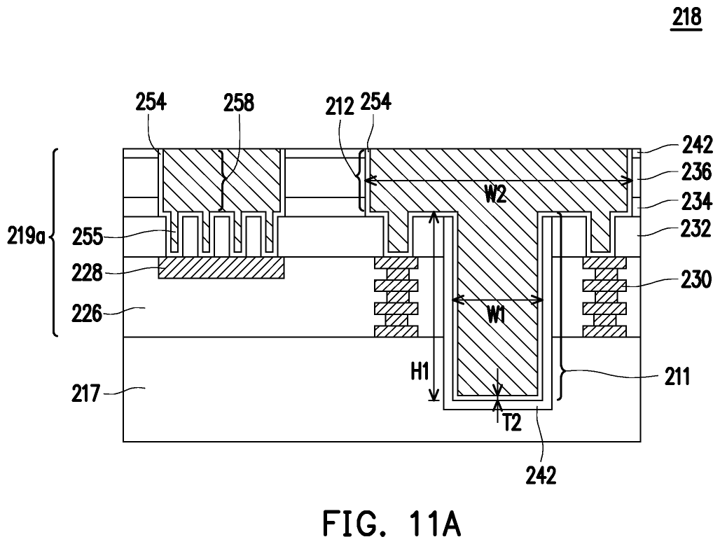

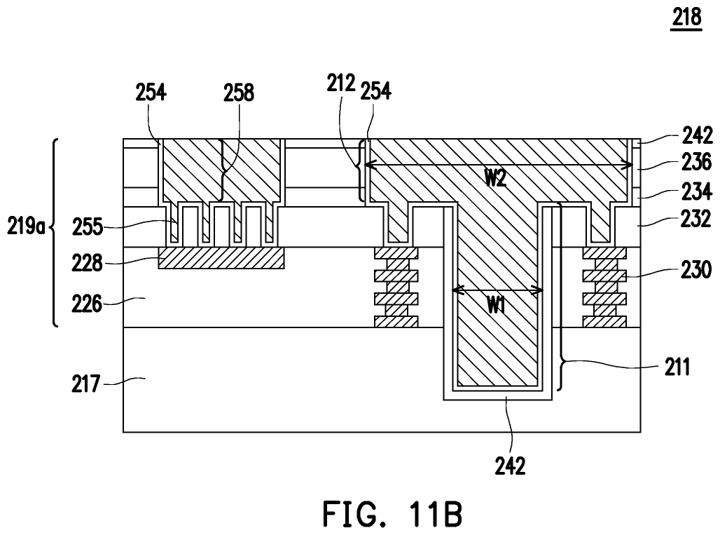

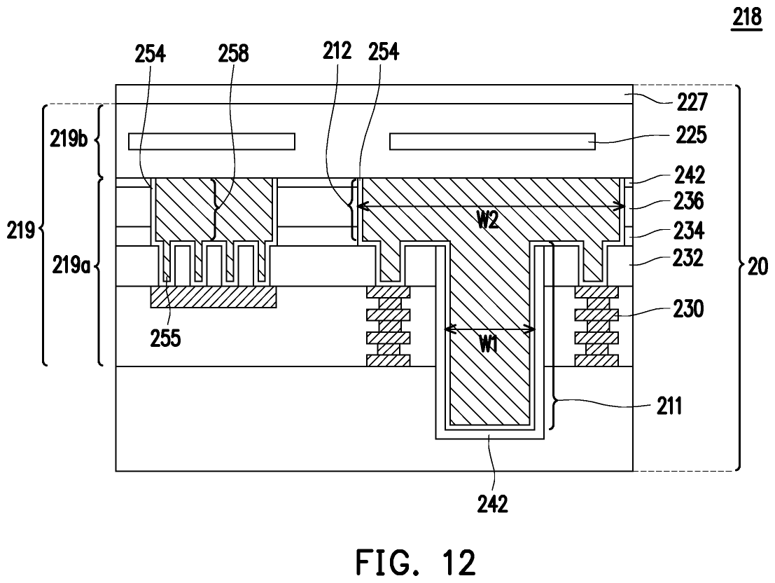

The wafer 20 further comprises through substrate vias (TSVs) 211 (also shown subsequently in FIGS. 11A through 12) that extend partially through the substrate 217 and partially through the interconnect structure 219. In addition, the wafer 20 comprises a first metallization layer (e.g., including conductive wirings, conductive pads, or the like). For example, the first metallization layer may include conductive pads 212 that are also shown subsequently in FIGS. 11A through 12. The conductive pads 212 extend partially through the interconnect structure 219, and are formed concurrently with the TSVs 211 such that the processes that are used to form the TSVs 211 are also used to form the conductive pads 212. In an embodiment, conductive wirings are used instead of the conductive pads 212. The conductive pads 212 and the TSVs 211 may comprise similar materials, and portions of the conductive pads 212 may be in physical contact with respective TSVs 211, wherein the conductive pads 212 are used to electrically connect the TSVs 211 to other external devices, other dies, or the metallization patterns 225 in the interconnect structure 219. In various embodiments, the back side of the wafer 20 may refer to a side of the wafer 20 on which a surface of the substrate 217 is exposed, and the front side of the wafer 20 may refer to a side of the wafer 20 on which the devices and the interconnect structure 219 are disposed.

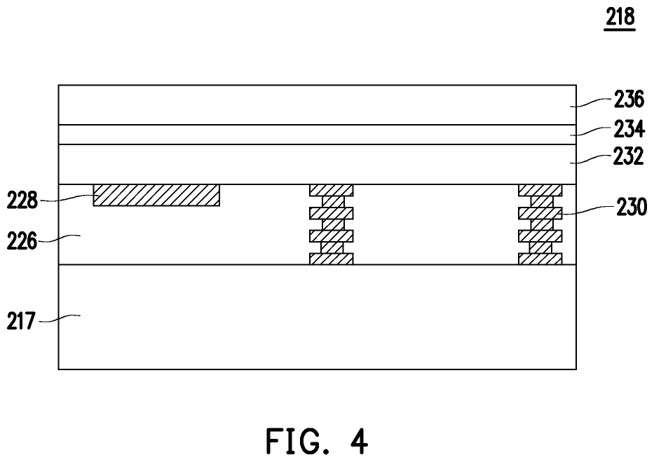

FIGS. 4 through 12 illustrate a region 218 of the wafer 20 that was shown in FIG. 3, and also illustrate intermediate steps during a process for forming the wafer 20, in accordance with some embodiments. FIGS. 4 through 11A illustrate the formation of a first portion of the interconnect structure 219a of the wafer 20. In addition, FIGS. 4 through 11A illustrate the formation of a TSV 211 in the region 218 of the wafer 20. It should be noted that the description of the of the formation process of the TSV 211 in FIGS. 4 through 11A can be applied to the formation of each TSV 211 in the wafer 20. In an embodiment, a plurality of TSVs 211 (e.g., as shown in FIG. 3) of the wafer 20 can be formed at the same time using the formation process described in FIGS. 4 through 11A. FIG. 12 illustrates the formation of a second portion of the interconnect structure 219b of the wafer 20. In FIG. 4, the region 218 (shown previously in FIG. 3) of the wafer 20 is illustrated. FIG. 4 further illustrates the substrate 217, and the formation of one or more dielectric layers 226 over the substrate 217. Guard ring structures 230 are also formed such that the guard ring structures 230 are embedded in the one or more dielectric layers 226, wherein the guard ring structures 230 are stacked in the one or more dielectric layers 226 to extend vertically through the one or more dielectric layers 226. The material of the one or more dielectric layers 226 may include silicon oxide, or the like, that is formed using a CVD process, an ALD process, or the like. Each dielectric layer 226 may be patterned using acceptable photolithography and etching techniques to form openings that correspond to a desired pattern for a respective guard ring structure 230 that is to be formed extending along the major surface of the dielectric layer 226 and extending through the dielectric layer 226. A conductive material is then formed in the openings in the dielectric layer 226 to form the respective guard ring structure 230 using for example, a PVD process, electroplating, electroless plating, a combination thereof, or the like. The conductive material may comprise a metal, like copper, titanium, tungsten, aluminum, a combination thereof, or the like. The guard ring structures 230 surround each one of the subsequently formed TSVs 211 (shown in FIG. 3 and FIGS. 11A through 12). The guard ring structures 230 may have multiple functions, such as, isolation, stress relief, current leakage prevention, electrostatic discharge (ESD) protection, the like, or a combination thereof. For example, to help prevent current leakage protection, the guard ring structures 230 may be grounded to help prevent or reduce electrical interference resulting from a current being carried through each of the TSVs 211.

One or more contact pads 228 are also formed in the one or more dielectric layers 226, to which electrical connections are made to the devices in and/or on the substrate 217. The one or more contact pads 228 may be embedded within the one or more dielectric layers 226. To form the contact pads 228, openings for the contact pads 228 are first formed in the one or more dielectric layers 226 using acceptable photolithography and etching techniques. A conductive material may then be formed in the openings using a deposition process such as sputtering, evaporation, CVD, plasma-enhanced chemical vapor deposition (PECVD), a plating process, an electroless plating process, a combination thereof, or the like. The conductive material may comprise copper, aluminum, or another conductive material. A planarization process is then performed to remove excess portions of the conductive material, and the remaining conductive material in the openings forms the contact pads 228.

After the one or more dielectric layers 226, the one or more contact pads 228, and the guard ring structures 230 have been formed as described above, a dielectric layer 232 is formed over the one or more dielectric layers 226, the one or more contact pads 228, and the guard ring structures 230. The dielectric layer 232 may comprise undoped Silicate Glass (USG), or the like, and can be formed using a CVD process, or the like. After the formation of the dielectric layer 232, a dielectric layer 234 is formed over the dielectric layer 232. The dielectric layer 234 may comprise silicon nitride, or the like. The dielectric layer 234 may be deposited by any suitable method, such as, CVD, ALD, or the like. In an embodiment, an additional dielectric layer (not shown in the Figures) may be formed over the dielectric layer 232 prior to the formation of the dielectric layer 234, using any suitable method, such as, CVD, ALD, or the like. The additional dielectric layer may comprise silicon carbide, or the like. After the formation of the dielectric layer 234, a dielectric layer 236 is formed over the dielectric layer 234. In an embodiment, materials of the dielectric layer 236 may be similar to the materials of the dielectric layer 232 that are described above. In an embodiment, the dielectric layer 236 may be formed using similar processes as those described above that were used for the formation of the dielectric layer 232.

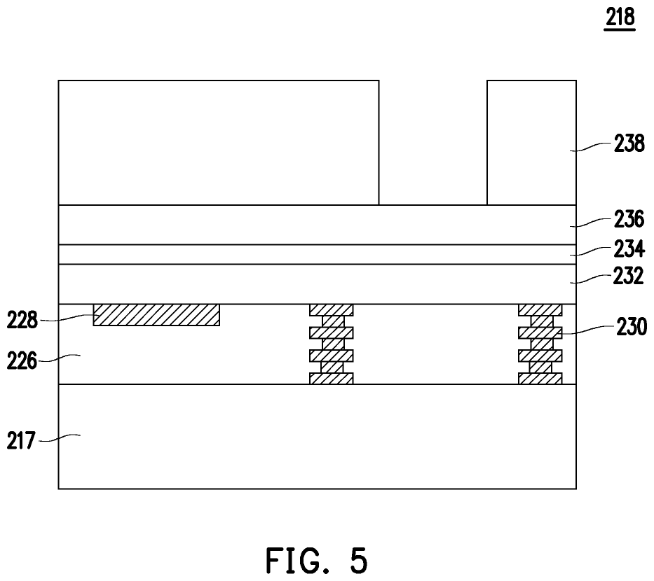

In FIG. 5, a mask layer 238 (e.g., a photoresist) is formed over the wafer 20, such as over the dielectric layer 236. The mask layer 238 is patterned using suitable development and exposure techniques to form openings in the mask layer that expose top surfaces of the dielectric layer 236.

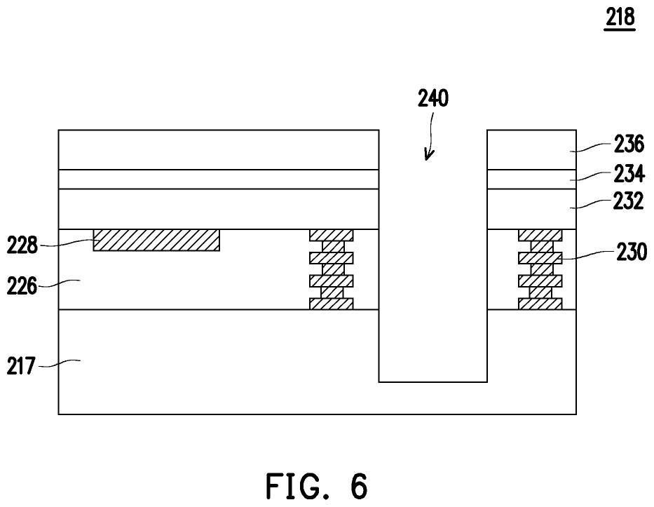

In FIG. 6, an etching process is performed using the mask layer 238 as an etching mask, in order to form openings 240 in the wafer 20. Each opening 240 may extend through the dielectric layer 236, the dielectric layer 234, the dielectric layer 232, and the one or more dielectric layers 226. In addition, the openings 240 may extend partially through the substrate 217. In an embodiment, each opening 240 may be surrounded by respective guard ring structures 230. In an embodiment, the etching process may comprise a wet etch process, a dry etch process, a combination thereof, or the like. For example, the etching process may comprise a dry plasma process, such as a deep reactive ion etching (DRIE) process using plasma gases that comprise sulphur hexafluoride (SF₆), Octafluorocyclobutane (C₄F₈), Fluoroform (CHF₃), or the like. The etching process may comprise a wet etch process that comprises Hydrogen fluoride (HF), or the like, as etchants. After the formation of the openings 240, the mask layer 238 is removed using an acceptable ashing or stripping process.

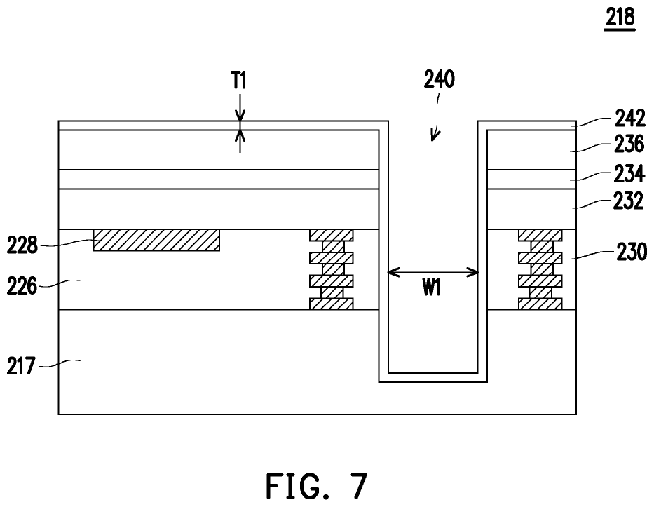

In FIG. 7, a dielectric liner 242 is deposited conformally over the wafer 20, such as over top surfaces of the dielectric layer 236 and within the openings 240. For example, the dielectric liner 242 is deposited on bottom surfaces in the openings 240, and on sidewalls of the substrate 217, the one or more dielectric layers 226, the dielectric layer 232, the dielectric layer 234, and the dielectric layer 236 within the openings 240. The dielectric liner 242 may comprise silicon oxide, or the like, and may be formed using a suitable process, such as CVD, ALD, or the like. In an embodiment, the dielectric liner 242 may have a thickness T1 that is in a range from 50 nm to 400 nm. In an embodiment, after the deposition of the dielectric liner 242, a width W1 of each opening 240 may be in a range from 0.5 μm to 14 um.

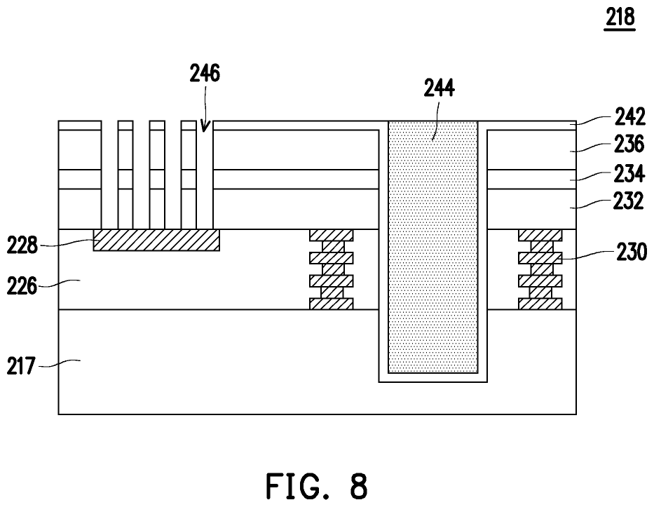

In FIG. 8, a Bottom Anti-Reflective Coating (BARC) layer 244 is formed over the dielectric liner 242 and in the openings 240 in order to fill the openings 240. The BARC layer 244 may be formed using a spin-coating process or the like. After the formation of the BARC layer 244, a planarization process is then performed to remove excess portions of the BARC layer 244, such that top surfaces of the dielectric liner 242 and top surfaces of the BARC layer 244 in the openings 240 are level (within process variations). The planarization process may comprise an etch-back process, or the like.

Referring further to FIG. 8, after the planarization process is performed, a mask layer (not shown in the Figures), such as a photoresist, or the like, is formed over the dielectric liner 242 and the BARC layer 244. The mask layer is then patterned using suitable development and exposure techniques to form openings in the mask layer. A suitable etching process is then performed to transfer the pattern of the mask layer to the dielectric liner 242, the dielectric layer 236, the dielectric layer 234, and the dielectric layer 232, and to form the openings 246. The openings 246 extend through the dielectric liner 242, the dielectric layer 236, the dielectric layer 234, and the dielectric layer 232, and expose top surfaces of the one or more contact pads 228. The openings 246 correspond to a desired pattern of the vias 255 that are shown subsequently in the FIGS. 11A through 12. The etching process may comprise a dry etch process that comprises Tetrafluoromethane (CF₄), Sulphur Hexafluoride (SF₆), Fluoroform (CHF₃), or the like, as etchants. After the formation of the openings 246, the mask layer is removed using an acceptable ashing or stripping process.

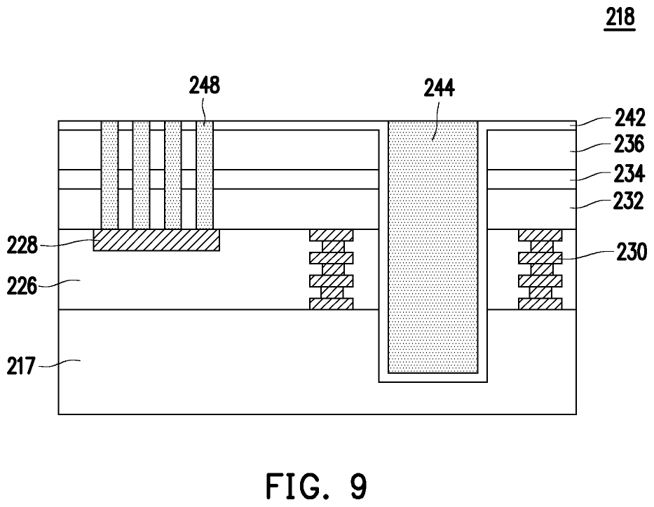

In FIG. 9, a Bottom Anti-Reflective Coating (BARC) layer 248 is formed over the dielectric liner 242, the BARC layer 244, and in the openings 246 in order to fill the openings 246. The BARC layer 248 may be formed using a spin-coating process or the like. After the formation of the BARC layer 248, a planarization process is then performed to remove excess portions of the BARC layer 248, such that top surfaces of the dielectric liner 242 and the BARC layer 244 are level (within process variations) with top surfaces of the BARC layer 248 in the openings 246. The planarization process may comprise an etch-back process, or the like.

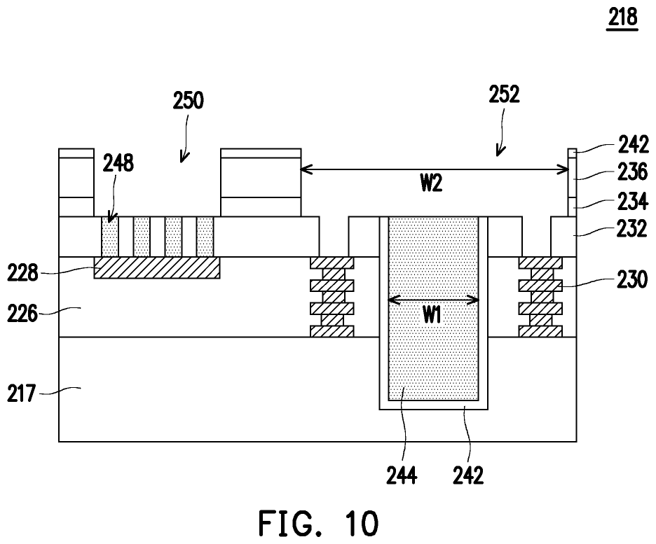

FIG. 10 illustrates that after the planarization process is performed, a mask layer (not shown in the Figures), such as a photoresist, or the like, is formed over the dielectric liner 242, the BARC layer 244, and the BARC layer 248. The mask layer is then patterned using suitable development and exposure techniques to form openings in the mask layer. A suitable etching process is then performed to transfer the pattern of the mask layer to the dielectric liner 242, the dielectric layer 236, and the dielectric layer 234, in order to form the openings 250 and the openings 252. The etching process is used to etch portions of the BARC layer 244, the BARC layer 248, the dielectric liner 242, the dielectric layer 236, and the dielectric layer 234 to form the openings 250 and the openings 252 that extend through the dielectric liner 242, the dielectric layer 236, and the dielectric layer 234, and expose top surfaces of the dielectric layer 232. Each opening 250 overlaps a corresponding contact pad 228, and exposes remaining portions of the BARC layer 248 that fills corresponding remaining portions of the openings 246 that extend through the dielectric layer 232. Each opening 252 overlaps and exposes a remaining portion of the BARC layer 244 that fills a corresponding remaining portion of the opening 240 that extends through the dielectric layer 232, the one or more dielectric layers 226, and the substrate 217. In an embodiment, each opening 252 may have a width W2, wherein the width W2 is greater than the width W1. In an embodiment, during the formation of the openings 252, the etching process may also be used to etch portions of the dielectric layer 232 that overlap the guard structures 230. In this way, each opening 252 may also extend through the dielectric layer 232 and expose top surfaces of the guard ring structures 230. The etching process may comprise a dry etch process that comprises Tetrafluoromethane (CF₄), Sulphur Hexafluoride (SF₆), Fluoroform (CHF₃) or the like, as etchants. After the formation of the openings 250 and the openings 252, the mask layer is removed using an acceptable ashing or stripping process.

In FIG. 11A, the BARC layer 248 is removed using a suitable etching process, resulting in remaining portions of the openings 246 in the dielectric layer 232 being re-formed in each respective opening 250. In addition, the etching process further removes the BARC layer 244, resulting in a remaining portion of the opening 240 in the dielectric layer 232, the one or more dielectric layers 226, and the substrate 217 being re-formed in each respective opening 252.

After the removal of the BARC layer 244 and the BARC layer 248, a barrier layer 254 may be conformally deposited over the dielectric liner 242 and in the openings 250, the remaining portions of the openings 246, the openings 252, and the remaining portions of the openings 240. The deposition of the barrier layer 254 may be performed using a suitable process such as by chemical vapor deposition (CVD), atomic layer deposition (ALD), physical vapor deposition (PVD), thermal oxidation, a combination thereof, and/or the like. The barrier layer 254 may comprise a nitride or an oxynitride, such as titanium nitride, titanium oxynitride, tantalum nitride, tantalum oxynitride, tungsten nitride, a combination thereof, and/or the like. In an embodiment, a thickness T2 of the barrier layer 254 may be in a range from 10 nm to 50 nm. A conductive material is deposited over the barrier layer 254 and in the openings 250, the remaining portions of the openings 246, the openings 252, and the remaining portions of the openings 240. The conductive material may be formed by an electro-chemical plating process, CVD, ALD, PVD, a combination thereof, and/or the like, such that the conductive material fills the openings 250, the remaining portions of the openings 246, the openings 252, and the remaining portions of the openings 240. Examples of conductive materials are copper, tungsten, aluminum, silver, gold, a combination thereof, and/or the like. Excess conductive material and the barrier layer 254 may be removed from over the dielectric liner 242 by performing a planarization process, such as chemical mechanical polishing, or the like. After the planarization process is performed, top surfaces of the conductive material, the barrier layer 254, and the dielectric liner 242 may be level (within process variations). Further, after the planarization process is performed, the conductive material and the barrier layer 254 in the remaining portions of the openings 246 of the dielectric layer 232 form the vias 255, and the conductive material and the barrier layer 254 in the remaining portions of the openings 240 form the TSVs 211. Each contact pad 228 may be physically and electrically connected to a respective plurality of vias 255. The conductive material and the barrier layer 254 in the openings 250 and the openings 252 form a first metallization layer that may include conductive wirings, conductive pads, or the like. For example, a first portion of the first metallization layer formed in each opening 250 may comprise a conductive pad 258, and a second portion of the first metallization layer formed in each opening 252 may comprise a conductive pad 212. Each conductive pad 258 is electrically connected to the devices in and/or on the substrate 217 through a respective plurality of vias 255 and a respective contact pad 228. Further, each conductive pad 212 is physically and electrically connected to a respective TSV 211. In an embodiment, the conductive pad 212 overlaps the respective TSV 211. In an embodiment, each conductive pad 212 also overlaps respective guard ring structures 230, wherein the conductive pad 212 is electrically and physically connected to the respective guard ring structures 230. In an embodiment, each TSV 211 may have a height H1, wherein a ratio (also referred to subsequently as the aspect ratio) of the height H1 to the width W1 may be in a range from 2:1 to 15:1.

Advantages can be achieved as a result of forming the wafer 20 comprising the TSVs 211 and the interconnect structure 219 (shown subsequently in FIG. 12), wherein each TSV 211 is electrically and physically connected to a respective conductive pad 212 in the interconnect structure 219. Forming the wafer 20 comprises the etching process to form the openings 240 that extend through the dielectric layer 236, the dielectric layer 234, the dielectric layer 232, and the one or more dielectric layers 226. The openings 240 also extend partially through the substrate 217, wherein the dielectric layer 236, the dielectric layer 234, the dielectric layer 232, and the one or more dielectric layers 226 are part of the interconnect structure 219. The dielectric liner 242 is then conformally deposited on bottom surfaces and sidewalls in the openings 240, wherein the dielectric liner 242 comprises an oxide, and has the thickness T1 that is in the range from 50 nm to 400 nm. The BARC layer 244 is formed over the dielectric liner 242 in the openings 240, wherein the BARC layer 244 fills the openings 240. Portions of the BARC layer 244, the dielectric liner 242, the dielectric layer 236, and the dielectric layer 234 are then etched to form the openings 252 that extend through the dielectric liner 242, the dielectric layer 236, and the dielectric layer 234, and expose top surfaces of the dielectric layer 232. Each opening 252 overlaps and exposes the BARC layer 244 that fills a corresponding remaining portion of the opening 240 that extends through the dielectric layer 232, the one or more dielectric layers 226, and the substrate 217. Another etching process is then performed to remove the remainder of the BARC layer 244, resulting in a remaining portion of the opening 240 in the dielectric layer 232, the one or more dielectric layers 226, and the substrate 217 being re-formed in each respective opening 252. After re-forming the remaining portions of the openings 240, the barrier layer 254 is concurrently formed in each opening 252 and its respective remaining portion of the opening 240 using the same process. After forming the barrier layer 254, the conductive material is concurrently formed in each opening 252 and its respective remaining portion of the opening 240 using the same process. The barrier layer 254 and the conductive material in the remaining portions of the openings 240 form the TSVs 211, and the barrier layer 254 and the conductive material in the openings 252 form the conductive pads 212, wherein each TSV 211 has the width W1, each conductive pad 212 has the width W2, and wherein the width W2 is greater than the width W1. Advantageous features of one or more embodiments disclosed herein may allow for each TSV 211 and its respective conductive pad 212 to be formed at the same time, such that the processes used to form the TSV 211 are also used to form the respective conductive pad 212. This allows a reduction in the number of process steps (e.g., including metal plating and planarization steps) that are needed to form the TSV 211 and the respective conductive pad 212, as compared to the number of process steps that would be needed to be performed if the TSV 211 and the respective conductive pad 212 were to be formed at different times using separate processes. As a result, manufacturing costs can be significantly reduced. In addition, concurrently forming the TSV 211 and the respective conductive pad 212 using the same processes allows for the TSV 211 and the respective conductive pad 212 to be in physical contact, without the barrier layer 254 being disposed between the TSV 211 and the respective conductive pad 212. As a result, the resistivity between the TSV 211 and the respective conductive pad 212 is reduced, allowing for more efficient electrical conduction, enhanced device performance, and reduced power consumption.

FIG. 11B illustrates an alternative embodiment. Unless specified otherwise, like reference numerals in this embodiment (and subsequently discussed embodiments) represent like components in the embodiment shown in FIGS. 1 through 11A formed by like processes. Accordingly, the process steps and applicable materials may not be repeated herein. The embodiment shown in FIG. 11B differs from the embodiment shown in FIG. 11A in that in the embodiment shown in FIG. 11B, the conductive pad 212 is not electrically and physically connected to the guard ring structures 230. No portion of the conductive pad 212 extends through the dielectric layer 232 to be in physical contact with the guard ring structures 230.

FIG. 12 illustrates the formation of the second portion of the interconnect structure 219b over the first portion of the interconnect structure 219a. The second portion of the interconnect structure 219b includes one or more dielectric layers (for example, one or more interlayer dielectric (ILD) layers, intermetal dielectric (IMD) layers, or the like) and the metallization patterns 225 (which may also be referred to subsequently as interconnect wirings) embedded in the one or more dielectric layers. The material of the one or more dielectric layers may include silicon oxide (SiOₓ, where x>0), silicon nitride (SiNₓ, where x>0), silicon oxynitride (SiOₓN_{y}, where x>0 and y>0), or other suitable dielectric material, which are formed by a suitable process, such as CVD, ALD, or the like. The metallization patterns 225 may include metallic wirings. For example, the metallization patterns 225 include copper wirings, copper pads, aluminum pads or combinations thereof that are formed by one or more single damascene processes, dual damascene processes, or the like. Each conductive pad 258 electrically connects a respective plurality of the vias 255 and a respective contact pad 228 to the metallization patterns 225. In addition, each conductive pad 212 electrically connects a respective TSV 211 to the metallization patterns 225.

Referring further to FIG. 12, after the formation of the second portion of the interconnect structure 219b, the dielectric layer 227 is formed over the second portion of the interconnect structure 219b, in order to complete the formation of the wafer 20 (shown previously in FIG. 3). The dielectric layer 227 may comprise silicon oxide, silicon nitride, silicon carbide, silicon oxynitride, Spin-On-Polymers, silicon carbon material, compounds thereof, composites thereof, combinations thereof, or the like. The dielectric layer 227 may be deposited by any suitable method, such as, CVD, PECVD, spinning, or the like.

In FIG. 13A, a thinning process of the back side of the wafer 20 (e.g., the exposed surface of the substrate 217) is performed to expose the TSVs 211 and the dielectric liner 242. The thinning process of the back side of the wafer 20 may be performed by a planarization process such as CMP, grinding, or etching. The thinning process may result in the exposed surfaces of the TSVs 211 being level with surfaces of the substrate 217 and the dielectric liner 242.

After the thinning process of the back side of the wafer 20 is performed, a bonding layer 221 is formed over the back side of the wafer 20, such as over the dielectric liner 242, the substrate 217 and the TSVs 211. The bonding layer 221 may comprise a dielectric layer. Bonding pads 223 are formed in the bonding layer 221, such that the bonding pads 223 are in physical contact with respective TSVs 211. The bonding pads 223 allow electrical connections to be made to the interconnect structure 219 and the devices on the substrate 217 through the TSVs 211. The material of the bonding layer 221 may be silicon oxide (SiOₓ, where x>0), silicon nitride (SiNₓ, where x>0), silicon oxynitride (SiOₓN_{y}, where x>0 and y>0), tetraethyl orthosilicate (TEOS), or other suitable dielectric material, and the bonding pads 223 may comprise conductive pads (e.g., copper pads), conductive vias (e.g., copper vias), or combinations thereof. The bonding layer 221 may be formed by depositing the dielectric material over the back side of the wafer 20 using a chemical vapor deposition (CVD) process (e.g., a plasma enhanced CVD process or other suitable process); patterning the dielectric material to form the bonding layer 221 including openings or through holes; and filling conductive material in the openings or through holes defined in the bonding layer 221 to form the bonding pads 223 embedded in the bonding layer 221.

Referring further to FIG. 13A, the semiconductor dies 150 (shown previously in FIG. 2) are bonded to the wafer 20, for example, in a hybrid bonding configuration. Each semiconductor die 150 may also be referred to subsequently as a top die. The semiconductor dies 150 are disposed face down and bonded to the wafer 20 in a face to back (F2B) bonding configuration as shown in FIGS. 13A and 13B, such that the front side of each semiconductor die 150 (e.g., the interconnect structure 119) is bonded to the back side of the wafer 20. For example, FIG. 13B illustrates a region 296 of the structure shown previously in FIG. 13A, wherein the region 296 includes a portion of a semiconductor die 150 and a portion of the wafer 20 that it is bonded to. The semiconductor dies 150 are bonded to the bonding layer 221 on the back side of the wafer 20 and the bonding pads 223 in the bonding layer 221. For example, the bonding layer 121 of the semiconductor dies 150 may be directly bonded to the bonding layer 221 on the wafer 20, and the bonding pads 123 of the semiconductor dies 150 may be directly bonded to the bonding pads 223 on the wafer 20. In an embodiment, the bond between the bonding layer 121 and the bonding layer 221 may be an oxide-to-oxide bond, or the like. The hybrid bonding process further directly bonds the bonding pads 123 of the semiconductor dies 150 to the bonding pads 223 on the wafer 20 through direct metal-to-metal bonding. Thus, electrical connection between the semiconductor die 150 and the wafer 20 is provided by the physical connection of the bonding pads 123 to the bonding pads 223.

As an example, the hybrid bonding process starts with aligning the semiconductor dies 150 with the wafer 20, for example, by applying a surface treatment to one or more of the bonding layer 121 or the bonding layer 221. The surface treatment may include a plasma treatment. The plasma treatment may be performed in a vacuum environment. After the plasma treatment, the surface treatment may further include a cleaning process (e.g., a rinse with deionized water, or the like) that may be applied to one or more of the bonding layer 121 or the bonding layer 221. The hybrid bonding process may then proceed to aligning the bonding pads 123 to the bonding pads 223. Next, the hybrid bonding includes a pre-bonding step, during which the semiconductor dies 150 are put in contact with the wafer 20. The pre-bonding may be performed at room temperature (e.g., between about 21° C. and about 25° C.). The hybrid bonding process continues with performing an anneal, for example, at a temperature between about 150° C. and about 400° C. for a duration between about 0.5 hours and about 3 hours, so that the metal in bonding pads 123 (e.g., copper) and the metal of the bonding pads 223 (e.g., copper) inter-diffuses to each other, and hence the direct metal-to-metal bonding is formed. Although four semiconductor dies 150 are illustrated as being bonded to the wafer 20, other embodiments may include any number of semiconductor dies 150 bonded to the wafer 20. The wafer 20 may comprise the first package region 200A and the second package region 200B, and one or more of the integrated chip package 100 are packaged to form an integrated circuit package in each of the package regions 200A and 200B.

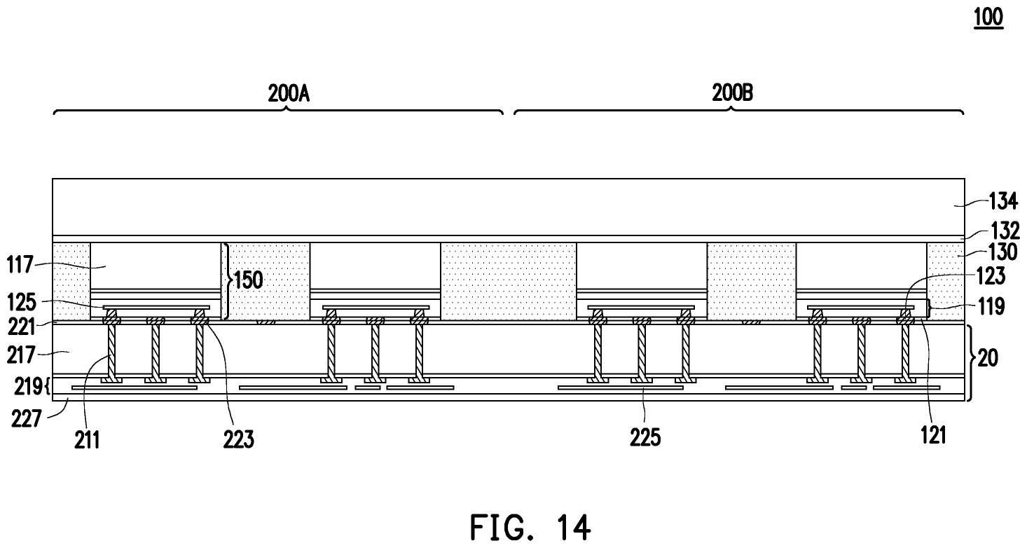

In FIG. 14, an encapsulant 130 is formed over the wafer 20 and the semiconductor dies 150, in order to encapsulate the semiconductor dies 150. The encapsulant 130 may be formed using compression molding, transfer molding, or the like. The encapsulant 130 may be an epoxy or a molding compound resin such as polyimide, polyphenylene sulfide (PPS), polyetheretherketone (PEEK), poly ether sulphone (PES), a heat resistant crystal resin, combinations of these, or the like.

FIG. 14 further illustrates a thinning process of the encapsulant 130 in order to expose top surfaces of the semiconductor dies 150. The thinning process may be performed, e.g., using a mechanical grinding, chemical approaches, or chemical mechanical polishing (CMP) process whereby chemical etchants and abrasives are utilized to react and grind away the encapsulant 130 so that the top surfaces of the semiconductor dies 150 have been exposed. After the thinning process, the top surfaces of the semiconductor dies 150 may have planar surfaces that are also coplanar with top surfaces of the encapsulant 130.

After the thinning process of the encapsulant 130 is performed, a carrier substrate 134 is attached to the top surfaces of the semiconductor dies 150 and the encapsulant 130. In an embodiment the carrier substrate 134 comprises, for example, silicon based materials, such as glass or silicon oxide, or other materials, such as aluminum oxide, combinations of any of these materials, or the like. The carrier substrate 134 is planar in order to accommodate the attachment of the semiconductor dies 150 and the encapsulant 130, which may be attached using a release layer 132. The release layer 132 may be formed of a polymer-based material, which may be removed along with the carrier substrate 134 from the overlying structures in subsequent steps. In some embodiments, the release layer 132 is an epoxy-based thermal-release material, which loses its adhesive property when heated, such as a light-to-heat-conversion (LTHC) release coating. In other embodiments, the release layer 132 may be a ultra-violet (UV) glue, which loses its adhesive property when exposed to UV lights. The release layer 132 may be dispensed as a liquid and cured, may be a laminate film laminated onto the carrier substrate 134, or may be the like. The top surface of the release layer 132 may be leveled and may have a high degree of planarity.

FIG. 15 illustrates a patterning of the dielectric layer 227 in order to form openings that extend through the dielectric layer 227 and expose portions of the metallization patterns 225 (e.g., conductive pads of the metallization patterns 225) in the interconnect structure 219. In an embodiment, the dielectric layer 227 may be patterned using, e.g., a laser drilling method. In such a method a protective layer, such as a light-to-heat conversion (LTHC) layer (not separately illustrated in FIG. 15) is first deposited over the dielectric layer 227. Once protected, a laser is directed towards those portions of the dielectric layer 227 which are desired to be removed in order to expose the underlying portions of the metallization patterns 225.

In another embodiment, the dielectric layer 227 may be patterned to form the openings that expose the portions of the metallization patterns 225 by initially applying a photoresist (not individually illustrated in FIG. 15) to the dielectric layer 227 and then exposing the photoresist to a patterned energy source (e.g., a patterned light source) so as to induce a chemical reaction, thereby inducing a physical change in those portions of the photoresist exposed to the patterned light source. A developer is then applied to the exposed photoresist to take advantage of the physical changes and selectively remove either the exposed portion of the photoresist or the unexposed portion of the photoresist, depending upon the desired pattern, and the underlying exposed portion of the dielectric layer 227 are removed with, e.g., a dry etch process. However, any other suitable method for patterning the dielectric layer 227 to form the openings may be utilized.

Conductive connectors 260 are then formed over the dielectric layer 227 and in the openings of the dielectric layer 227. The conductive connectors 260 are electrically coupled to the semiconductor dies 150 through the interconnect structure 219 (e.g., including the conductive pads 212 and the TSVs 211). The conductive connectors 260 are also electrically coupled to the contact pads 228 through the interconnect structure 219 (e.g., including the vias 255 and the conductive pads 258). The conductive connectors 260 may comprise controlled collapse chip connection (C4) bumps, ball grid array (BGA) connectors, solder balls, or the like. The conductive connectors 260 may comprise a conductive material such as solder, copper, aluminum, gold, nickel, silver, palladium, tin, the like, or a combination thereof. In some embodiments, the conductive connectors 260 are formed by initially forming a layer of solder through evaporation, electroplating, printing, solder transfer, ball placement, or the like. Once a layer of solder has been formed on the structure, a reflow may be performed in order to shape the material into the desired bump shapes.

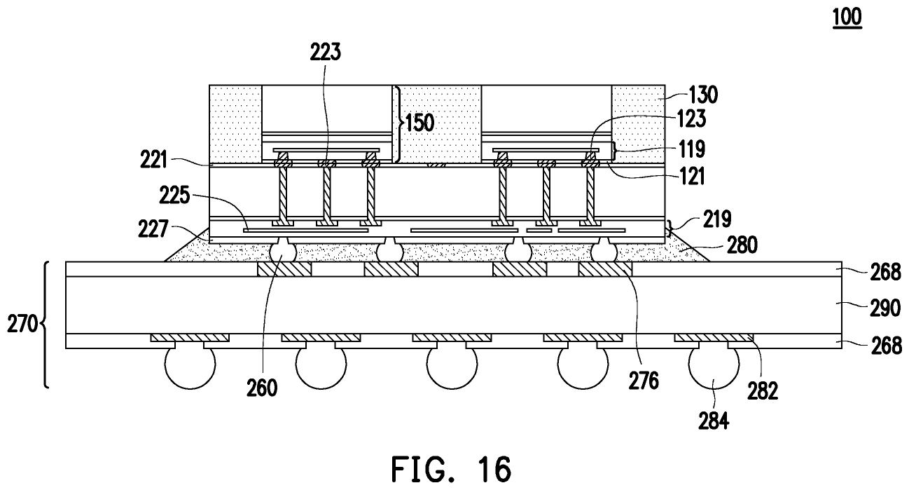

In FIG. 16, a de-bonding of the carrier substrate 134 is then performed to detach (or “de-bond”) the carrier substrate 134 from the semiconductor dies 150 and the encapsulant 130. In accordance with some embodiments, the de-bonding includes projecting a light such as a laser light or an UV light on the release layer 132 so that the release layer 132 decomposes under the heat of the light. The carrier substrate 134 can then be mechanically removed from the integrated chip package 100.

After the de-bonding of the carrier substrate 134 from the semiconductor dies 150 and the encapsulant 130, a singulation process is performed by sawing along scribe line regions 202, e.g., between the first package region 200A and the second package region 200B (shown previously in FIG. 15). The sawing singulates the first package region 200A from the second package region 200B, resulting in singulated device stacks from each of the first package region 200A and the second package region 200B.

Referring further to FIG. 16, a package substrate 270 is coupled to one of the singulated device stacks from one of the first package region 200A or the second package region 200B. The package substrate 270 may comprise an interposer, a package, a core substrate, a coreless substrate, a printed circuit board (PCB), or the like. In an embodiment, the package substrate 270 includes a substrate core 290 and bond pads 276 over the substrate core 290. The substrate core 290 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 290 may be an SOI substrate. Generally, an SOI substrate includes a layer of a semiconductor material such as epitaxial silicon, germanium, silicon germanium, SOI, SGOI, or combinations thereof. The substrate core 290 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 290.

The substrate core 290 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 290 may also include metallization layers and vias (not shown), with the bond pads 276 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 290 is substantially free of active and passive devices.

In some embodiments, the conductive connectors 260 are reflowed to attach the interconnect structure 219 to the bond pads 276. The conductive connectors 260 electrically and/or physically couple the package substrate 270, including metallization layers in the substrate core 290, to the interconnect structure 219. In some embodiments, a solder resist 268 is formed on the substrate core 290. The conductive connectors 260 may be disposed in openings in the solder resist 268 to be electrically and mechanically coupled to the bond pads 276. The solder resist 268 may be used to protect areas of the substrate core 290 from external damage.

The conductive connectors 260 may have an epoxy flux (not shown) formed thereon before they are reflowed with at least some of the epoxy portion of the epoxy flux remaining after the interconnect structure 219 is attached to the package substrate 270. This remaining epoxy portion may act as an underfill to reduce stress and protect the joints resulting from reflowing the conductive connectors 260. In some embodiments, an underfill 280 may be formed between the interconnect structure 219 and the package substrate 270 and surrounding the conductive connectors 260. The underfill 280 may be formed by a capillary flow process after the coupling of the interconnect structure 219 to the package substrate 270 or may be formed by a suitable deposition method before the package substrate 270 is coupled to the interconnect structure 219.

In an embodiment, the package substrate 270 may comprise bond pads 282 over the substrate core 290. Conductive connectors 284 may be coupled to the bond pads 282 to allow for the electrical coupling of the package substrate 270 to external circuits or devices. The conductive connectors 284 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 284 may include a conductive material such as solder, copper, aluminum, gold, nickel, silver, palladium, tin, the like, or a combination thereof. In some embodiments, the solder resist 268 is formed on the substrate core 290 and the conductive connectors 284 may be disposed in openings in the solder resist 268 to be electrically and mechanically coupled to the bond pads 282. The solder resist 268 may be used to protect areas of the substrate core 290 from external damage.

In some embodiments, passive devices (e.g., surface mount devices (SMDs), not shown) may also be attached to the package substrate 270 (e.g., to the bond pads 276). For example, the passive devices may be bonded to a same surface of the package substrate 270 as the conductive connectors 260.

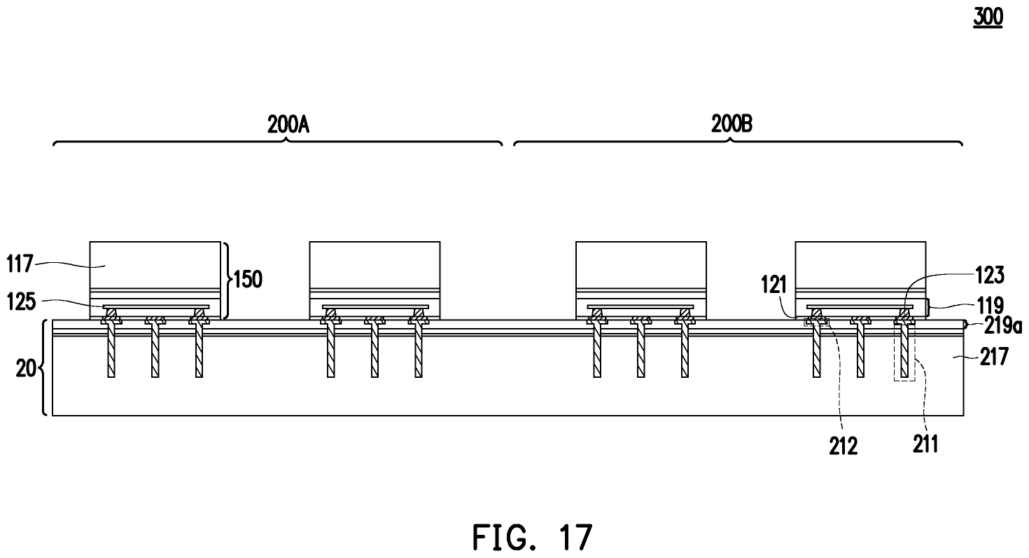

FIGS. 17 through 19 illustrate cross-sectional views of intermediate steps during a process for forming an integrated chip package 300, in accordance with alternative embodiments. Unless specified otherwise, like reference numerals in this embodiment (and subsequently discussed embodiments) represent like components in the embodiment shown in FIGS. 1 through 16 formed by like processes. Accordingly, the process steps and applicable materials may not be repeated herein. The initial steps of this embodiment are essentially the same as shown in FIGS. 1 through 11B. However, the formation of the second portion of the interconnect structure 219b over the first portion of the interconnect structure 219a as shown in FIG. 12 is omitted, such that the wafer 20 does not comprise the second portion of the interconnect structure 219b over the dielectric liner 242, the conductive pads 212, and the conductive pads 258 of the first portion of the interconnect structure 219a.

In FIG. 17, the semiconductor dies 150 are bonded to the wafer 20, for example, in a hybrid bonding configuration. Each semiconductor die 150 may also be referred to subsequently as a top die. The semiconductor dies 150 are disposed face down and bonded to the wafer 20, such that the front side of each semiconductor die 150 is bonded to the front side of the wafer 20. The semiconductor dies 150 are bonded to the dielectric liner 242 (described previously in FIGS. 7 through 11B) and the conductive pads 212 (described previously in FIGS. 7 through 11B) of the first portion of the interconnect structure 219a. For example, the bonding layer 121 of the semiconductor dies 150 may be directly bonded to the dielectric liner 242 of the wafer 20, and the bonding pads 123 of the semiconductor dies 150 may be directly bonded to the conductive pads 212 of the wafer 20. In an embodiment, one or more of the bonding pads 123 of the semiconductor dies 150 may also be directly bonded to respective conductive pads 258 of the wafer 20. In an embodiment, the bond between the bonding layer 121 and the dielectric liner 242 may be an oxide-to-oxide bond, or the like. The hybrid bonding process further directly bonds the bonding pads 123 of the semiconductor dies 150 to the conductive pads 212 of the wafer 20 through direct metal-to-metal bonding. Thus, electrical connection between the semiconductor die 150 and the wafer 20 is provided by the physical connection of the bonding pads 123 to the conductive pads 212.

As an example, the hybrid bonding process starts with aligning the semiconductor dies 150 with the wafer 20, for example, by applying a surface treatment to one or more of the bonding layer 121 or the dielectric liner 242. The surface treatment may include a plasma treatment. The plasma treatment may be performed in a vacuum environment. After the plasma treatment, the surface treatment may further include a cleaning process (e.g., a rinse with deionized water, or the like) that may be applied to one or more of the bonding layer 121 or the dielectric liner 242. The hybrid bonding process may then proceed to aligning the bonding pads 123 to the conductive pads 212. Next, the hybrid bonding includes a pre-bonding step, during which the semiconductor dies 150 are put in contact with the wafer 20. The pre-bonding may be performed at room temperature (e.g., between about 21° C. and about 25° C.). The hybrid bonding process continues with performing an anneal, for example, at a temperature between about 150° C. and about 400° C. for a duration between about 0.5 hours and about 3 hours, so that the metal in bonding pads 123 (e.g., copper) and the metal of the conductive pads 212 (e.g., copper) inter-diffuses to each other, and hence the direct metal-to-metal bonding is formed. Although four semiconductor dies 150 are illustrated as being bonded to the wafer 20, other embodiments may include any number of semiconductor dies 150 bonded to the wafer 20. The wafer 20 may comprise the first package region 200A and the second package region 200B, and one or more of the integrated chip package 300 are packaged to form an integrated circuit package in each of the package regions 200A and 200B.

Advantages can be achieved as a result of forming the wafer 20 comprising the TSVs 211 and the interconnect structure 219a (shown in FIGS. 17-20), wherein each TSV 211 is electrically and physically connected to a respective conductive pad 212 in the interconnect structure 219a. Forming the wafer 20 comprises the etching process to form the openings 240 that extend through the dielectric layer 236, the dielectric layer 234, the dielectric layer 232, and the one or more dielectric layers 226. The openings 240 also extend partially through the substrate 217, wherein the dielectric layer 236, the dielectric layer 234, the dielectric layer 232, and the one or more dielectric layers 226 are part of the interconnect structure 219a. The dielectric liner 242 is then conformally deposited on bottom surfaces and sidewalls in the openings 240, wherein the dielectric liner 242 comprises an oxide, and has the thickness T1 that is in the range from 50 nm to 400 nm. The BARC layer 244 is formed over the dielectric liner 242 in the openings 240, wherein the BARC layer 244 fills the openings 240. Portions of the BARC layer 244, the dielectric liner 242, the dielectric layer 236, and the dielectric layer 234 are then etched to form the openings 252 that extend through the dielectric liner 242, the dielectric layer 236, and the dielectric layer 234, and expose top surfaces of the dielectric layer 232. Each opening 252 overlaps and exposes the BARC layer 244 that fills a corresponding remaining portion of the opening 240 that extends through the dielectric layer 232, the one or more dielectric layers 226, and the substrate 217. Another etching process is then performed to remove the remainder of the BARC layer 244, resulting in a remaining portion of the opening 240 in the dielectric layer 232, the one or more dielectric layers 226, and the substrate 217 being re-formed in each respective opening 252. After re-forming the remaining portions of the openings 240, the barrier layer 254 is concurrently formed in each opening 252 and its respective remaining portion of the opening 240 using the same process. After forming the barrier layer 254, the conductive material is concurrently formed in each opening 252 and its respective remaining portion of the opening 240 using the same process. The barrier layer 254 and the conductive material in the remaining portions of the openings 240 form the TSVs 211, and the barrier layer 254 and the conductive material in the openings 252 form the conductive pads 212, wherein each TSV 211 has the width W1, each conductive pad 212 has the width W2, and wherein the width W2 is greater than the width W1. Advantageous features of one or more embodiments disclosed herein may allow for each TSV 211 and its respective conductive pad 212 to be formed at the same time, such that the processes used to form the TSV 211 are also used to form the respective conductive pad 212. This allows a reduction in the number of process steps (e.g., including metal plating and planarization steps) that are needed to form the TSV 211 and the respective conductive pad 212, as compared to the number of process steps that would be needed to be performed if the TSV 211 and the respective conductive pad 212 were to be formed at different times using separate processes. As a result, manufacturing costs can be significantly reduced. In addition, concurrently forming the TSV 211 and the respective conductive pad 212 using the same processes allows for the TSV 211 and the respective conductive pad 212 to be in physical contact, without the barrier layer 254 being disposed between the TSV 211 and the respective conductive pad 212. As a result, the resistivity between the TSV 211 and the respective conductive pad 212 is reduced, allowing for more efficient electrical conduction, enhanced device performance, and reduced power consumption.

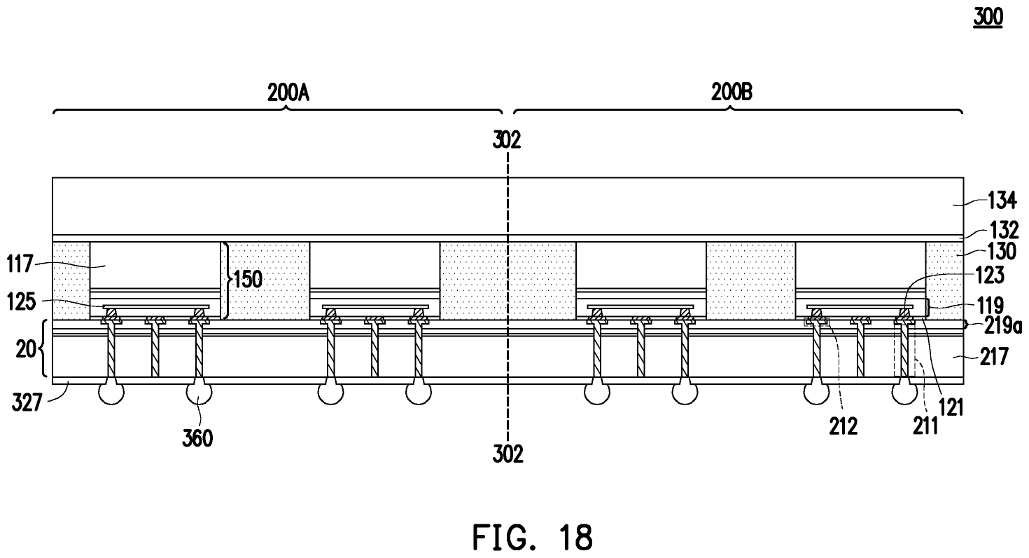

In FIG. 18, the encapsulant 130 is formed over the wafer 20 and the semiconductor dies 150 using similar materials and processes as were described previously for the formation of the encapsulant 130 in FIG. 14. After the encapsulant 130 is formed, a thinning process of the encapsulant 130 is performed in order to expose top surfaces of the semiconductor dies 150. The thinning process may be performed using similar processes as those described previously in FIG. 14 to thin the encapsulant 130. After the thinning process, the top surfaces of the semiconductor dies 150 may have planar surfaces that are also coplanar with top surfaces of the encapsulant 130.

After the thinning process of the encapsulant 130 is performed, the carrier substrate 134 is attached to the top surfaces of the semiconductor dies 150 and the encapsulant 130 using similar processes and materials as were described previously in FIG. 14. For example, the carrier substrate 134 is attached to the top surfaces of the semiconductor dies 150 and the encapsulant 130 using the release layer 132 as described previously in FIG. 14.

Referring further to FIG. 18, a thinning process of the back side of the wafer 20 (e.g., the exposed surface of the substrate 217) is performed to expose the TSVs 211 and the dielectric liner 242. The thinning process of the back side of the wafer 20 may be performed by a planarization process such as CMP, grinding, or etching. The thinning process may result in the exposed surfaces of the TSVs 211 being level with surfaces of the substrate 217 and the dielectric liner 242.

After the thinning process to expose the TSVs 211 is performed, a dielectric layer 327 may be formed on the back side of the wafer 20, such as over the exposed TSVs 211, the dielectric liner 242, and the surface of the substrate 217. The dielectric layer 327 may comprise silicon oxide, silicon nitride, silicon carbide, silicon oxynitride, Spin-On-Polymers, silicon carbon material, compounds thereof, composites thereof, combinations thereof, or the like. The dielectric layer 327 may be deposited by any suitable method, such as, CVD, PECVD, spinning, or the like. FIG. 18 additionally illustrates a patterning of the dielectric layer 327 in order to form openings that expose the TSVs 211. In an embodiment, the dielectric layer 327 may be patterned using, e.g., a laser drilling method. In such a method a protective layer, such as a light-to-heat conversion (LTHC) layer (not separately illustrated in FIG. 18) is first deposited over the dielectric layer 327. Once protected, a laser is directed towards those portions of the dielectric layer 327 which are desired to be removed in order to expose the underlying TSVs 211.

In another embodiment, the dielectric layer 327 may be patterned to form the openings that expose the TSVs 211 by initially applying a photoresist (not individually illustrated in FIG. 18) to the dielectric layer 327 and then exposing the photoresist to a patterned energy source (e.g., a patterned light source) so as to induce a chemical reaction, thereby inducing a physical change in those portions of the photoresist exposed to the patterned light source. A developer is then applied to the exposed photoresist to take advantage of the physical changes and selectively remove either the exposed portion of the photoresist or the unexposed portion of the photoresist, depending upon the desired pattern, and the underlying exposed portion of the dielectric layer 327 are removed with, e.g., a dry etch process. However, any other suitable method for patterning the dielectric layer 327 to form the openings may be utilized.

Conductive connectors 360 are then formed over the dielectric layer 327 and in the openings of the dielectric layer 327. The conductive connectors 360 are electrically coupled to the semiconductor dies 150 through the TSVs 211 and the conductive pads 212. The conductive connectors 360 may comprise controlled collapse chip connection (C4) bumps, ball grid array (BGA) connectors, solder balls, or the like. The conductive connectors 360 may comprise a conductive material such as solder, copper, aluminum, gold, nickel, silver, palladium, tin, the like, or a combination thereof. In some embodiments, the conductive connectors 360 are formed by initially forming a layer of solder through evaporation, electroplating, printing, solder transfer, ball placement, or the like. Once a layer of solder has been formed on the structure, a reflow may be performed in order to shape the material into the desired bump shapes.

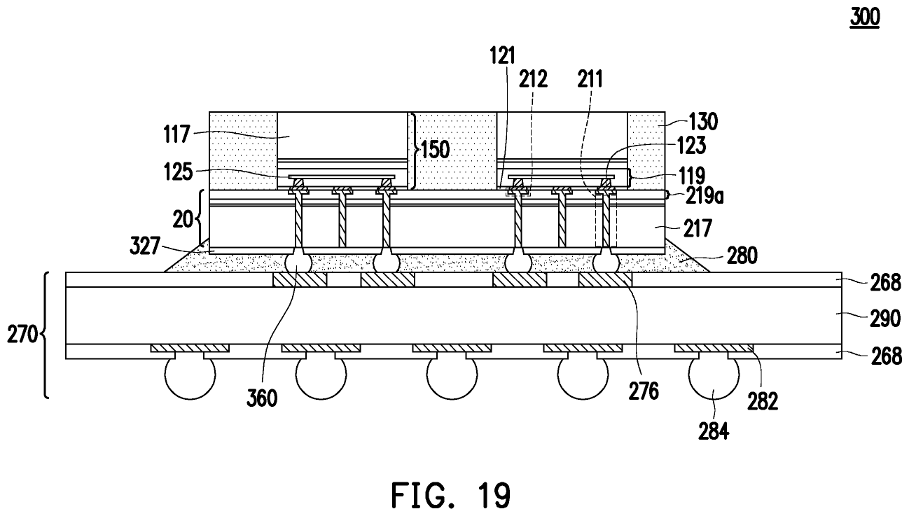

In FIG. 19, a de-bonding of the carrier substrate 134 is then performed to detach (or “de-bond”) the carrier substrate 134 from the semiconductor dies 150 and the encapsulant 130. In accordance with some embodiments, the de-bonding includes projecting a light such as a laser light or an UV light on the release layer 132 so that the release layer 132 decomposes under the heat of the light. The carrier substrate 134 can then be mechanically removed from the integrated chip package 300.

After the de-bonding of the carrier substrate 134 from the semiconductor dies 150 and the encapsulant 130, a singulation process is performed by sawing along scribe line regions 302, e.g., between the first package region 200A and the second package region 200B (shown previously in FIG. 18). The sawing singulates the first package region 200A from the second package region 200B, resulting in singulated device stacks from each of the first package region 200A and the second package region 200B.

Referring further to FIG. 19, the package substrate 270 (described previously in FIG. 16) is coupled to one of the singulated device stacks from one of the first package region 200A or the second package region 200B. In some embodiments, the conductive connectors 360 are reflowed to attach the wafer 20 to the bond pads 276. The conductive connectors 360 electrically and/or physically couple the package substrate 270, including metallization layers in the substrate core 290, to the TSVs 211 and the conductive pads 212. In some embodiments, a solder resist 268 is formed on the substrate core 290. The conductive connectors 360 may be disposed in openings in the solder resist 268 to be electrically and mechanically coupled to the bond pads 276. The solder resist 268 may be used to protect areas of the substrate core 290 from external damage.

The conductive connectors 360 may have an epoxy flux (not shown) formed thereon before they are reflowed with at least some of the epoxy portion of the epoxy flux remaining after the wafer 20 is attached to the package substrate 270. This remaining epoxy portion may act as an underfill to reduce stress and protect the joints resulting from reflowing the conductive connectors 360. In some embodiments, the underfill 280 may be formed between the wafer 20 and the package substrate 270 and surrounding the conductive connectors 360. The underfill 280 may be formed by a capillary flow process after the coupling of the wafer 20 to the package substrate 270 or may be formed by a suitable deposition method before the package substrate 270 is coupled to the wafer 20.

The embodiments of the present disclosure have some advantageous features. The embodiments include a method applied to forming a through-substrate via (TSV) that extends through a bottom semiconductor device (e.g., a bottom die). A top semiconductor device (e.g., a top die) is then bonded to the bottom semiconductor device (e.g., the bottom die) to form a vertical stack in order to provide a 3D integrated chip (3DIC) package. The TSV may be used for signal or power transmission between the bottom semiconductor device and the top semiconductor device. The TSV may be formed to extend through a semiconductor substrate of the bottom semiconductor device and may also extend through a portion of an interconnect structure that is formed over the semiconductor substrate. A first metallization layer (e.g., including conductive wirings, a conductive pad, or the like) is formed concurrently with the TSV and is disposed within the interconnect structure, such that the processes that are used to form the TSV are also used to form the first metallization layer. The first metallization layer and the TSV may comprise similar materials, and may be in physical contact with each other, wherein the first metallization layer is used to electrically connect the TSV to other metallization layers disposed in the interconnect structure, external devices, or other dies. As a result, the TSV and the first metallization layer can be formed at the same time, such that the processes used to form the TSV are also used to form the first metallization layer. This allows a reduction in the number of process steps (e.g., including metal plating and planarization steps) that are needed to form the TSV and the first metallization layer, as compared to the number of process steps that would be needed to be performed if the TSV and the first metallization layer were to be formed at different times using separate processes. As a result, manufacturing costs can be significantly reduced. In addition, concurrently forming the TSV and the first metallization layer using the same processes allows for the TSV and the first metallization layer to be in physical contact, without a barrier layer being disposed between the TSV and the first metallization layer. As a result, the resistivity between the TSV and the first metallization layer is reduced, allowing for more efficient electrical conduction, enhanced device performance, and reduced power consumption.

In accordance with an embodiment, a method of manufacturing a semiconductor device includes forming a first wafer, where forming the first wafer includes forming a plurality of first dielectric layers over a first surface of a semiconductor substrate, the first surface being on a first side of the semiconductor substrate; depositing a second dielectric layer over the plurality of first dielectric layers; forming a first opening that extends through the second dielectric layer, the plurality of first dielectric layers, and partially through the semiconductor substrate; filling the first opening with a first Bottom Anti-Reflective Coating (BARC) layer; etching portions of the first BARC layer and the second dielectric layer to form a second opening, where the second opening overlaps and exposes a remaining portion of the first BARC layer in a remaining portion of the first opening; removing the first BARC layer; and concurrently forming a first through substrate via (TSV) in the remaining portion of the first opening and a first conductive pad in the second opening. In an embodiment, forming the first wafer further includes prior to filling the first opening with the first BARC layer, conformally depositing a dielectric liner on a bottom surface and sidewalls in the first opening. In an embodiment, concurrently forming the first TSV in the remaining portion of the first opening and the first conductive pad in the second opening includes conformally depositing a barrier layer in the first opening and the second opening using a first process; and depositing a conductive material over the barrier layer in the first opening and the second opening using a second process. In an embodiment, the first TSV has a first width, the first conductive pad has a second width, and the second width is greater than the first width. In an embodiment, the method further includes planarizing a second surface of the semiconductor substrate to expose the first TSV, the second surface being on a second side of the semiconductor substrate, the second side being on an opposite side of the semiconductor substrate as the first side. In an embodiment, the method further includes forming a first bonding layer over the exposed first TSV and on the second side of the semiconductor substrate; forming a first bonding pad in the first bonding layer; and bonding a first semiconductor die to the first wafer, where the bonding includes bonding the first bonding layer to a second bonding layer of the first semiconductor die using direct oxide-to-oxide bonding; and bonding the first bonding pad to a second bonding pad of the first semiconductor die using direct metal-to-metal bonding, where the first bonding pad is in physical contact with the first TSV. In an embodiment, forming the first wafer further includes forming a guard ring structure in the plurality of first dielectric layers, where the guard ring structure surrounds the first TSV and is in physical contact with the first conductive pad.

In accordance with an embodiment, a method of manufacturing a semiconductor device includes forming a first wafer, the first wafer including a first interconnect structure over a semiconductor substrate, where forming the first wafer includes forming a plurality of first dielectric layers over the semiconductor substrate; depositing a second dielectric layer over the plurality of first dielectric layers; forming a first opening that extends through the second dielectric layer, the plurality of first dielectric layers, and partially through the semiconductor substrate; depositing a dielectric liner over the second dielectric layer and on a bottom surface and sidewalls in the first opening; etching portions of the dielectric liner and the second dielectric layer to form a second opening, where the second opening overlaps a remaining portion of the first opening; and concurrently forming a first through substrate via (TSV) in the remaining portion of the first opening and a first conductive pad in the second opening. In an embodiment, forming the first wafer further includes filling the first opening with a first Bottom Anti-Reflective Coating (BARC) layer; and etching a top portion of the first BARC layer, where after etching the top portion of the first BARC layer, and after etching the portions of the dielectric liner and the second dielectric layer to form the second opening, a topmost surface of a remaining portion of the first BARC layer in the remaining portion of the first opening is level with a bottom surface of the second opening. In an embodiment, forming the first TSV in the remaining portion of the first opening and the first conductive pad in the second opening includes removing the remaining portion of the first BARC layer in the remaining portion of the first opening; and depositing a conductive material in the second opening and the remaining portion of the first opening. In an embodiment, the first TSV has a first width, the first conductive pad has a second width, and the second width is greater than the first width. In an embodiment, forming the first wafer further includes forming a contact pad in the plurality of first dielectric layers; forming a third opening that extends through the second dielectric layer and the dielectric liner; and during concurrently forming the first TSV in the remaining portion of the first opening and the first conductive pad in the second opening, forming a second conductive pad in the third opening, the second conductive pad being electrically connected to the contact pad in the plurality of first dielectric layers. In an embodiment, the method further includes bonding a first semiconductor die to the first wafer, where the bonding includes bonding a first bonding layer of the first semiconductor die to the dielectric liner using direct oxide-to-oxide bonding; and bonding a first bonding pad of the first semiconductor die to the first conductive pad using direct metal-to-metal bonding. In an embodiment, the method further includes forming a guard ring structure in the plurality of first dielectric layers, where the guard ring structure surrounds the first TSV, and where the guard ring structure is electrically connected to the first conductive pad.

In accordance with an embodiment, a package includes a first die including a first interconnect structure on a first side of a first semiconductor substrate, the first interconnect structure includes a plurality of first dielectric layers; a second dielectric layer over the plurality of first dielectric layers; and a dielectric liner over the second dielectric layer, where a first conductive pad is disposed to extend through the dielectric liner and the second dielectric layer, and a first through substrate via (TSV) is disposed to extend through the plurality of first dielectric layers and the first semiconductor substrate, where the dielectric liner is also disposed on sidewalls of the first TSV, and where the first TSV and the first conductive pad are in physical contact; a second die over and bonded to the first die, the second die including a first bonding layer over a second semiconductor substrate; and a first bonding pad disposed in the first bonding layer, where a bond between the first bonding layer of the second die and the dielectric liner is an oxide-to-oxide bond, and a bond between the first bonding pad of the second die and the first conductive pad is a metal-to-metal bond. In an embodiment, the first conductive pad is disposed over the first TSV, where each of the first TSV and the first conductive pad include a conductive material; and a barrier layer on sidewalls of the conductive material, where the barrier layer is not disposed between the conductive material of the first TSV and the conductive material of the first conductive pad, and where the barrier layer is disposed on a portion of a bottom surface of the conductive material of the first conductive pad. In an embodiment, a first width of the first conductive pad is greater than a second width of the first TSV. In an embodiment, the package further includes a package substrate coupled to a second side of the first semiconductor substrate using conductive connectors, where the second side is on an opposite side of the first semiconductor substrate as the first side. In an embodiment, a material of the dielectric liner and a material of the second dielectric layer are different. In an embodiment, the package further includes a guard ring structure disposed in the plurality of first dielectric layers, where the guard ring structure surrounds the first TSV, and where the guard ring structure is electrically coupled to the first conductive pad.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
forming a first wafer, wherein forming the first wafer comprises:
forming a plurality of first dielectric layers over a first surface of a semiconductor substrate, the first surface being on a first side of the semiconductor substrate;
depositing a second dielectric layer over the plurality of first dielectric layers;
forming a first opening that extends through the second dielectric layer, the plurality of first dielectric layers, and partially through the semiconductor substrate;
filling the first opening with a first Bottom Anti-Reflective Coating (BARC) layer;
etching portions of the first BARC layer and the second dielectric layer to form a second opening, wherein the second opening overlaps and exposes a remaining portion of the first BARC layer in a remaining portion of the first opening;
removing the first BARC layer; and
concurrently forming a first through substrate via (TSV) in the remaining portion of the first opening and a first conductive pad in the second opening.

2. The method of claim 1, wherein forming the first wafer further comprises:
prior to filling the first opening with the first BARC layer, conformally depositing a dielectric liner on a bottom surface and sidewalls in the first opening.

3. The method of claim 1, wherein concurrently forming the first TSV in the remaining portion of the first opening and the first conductive pad in the second opening comprises:
conformally depositing a barrier layer in the first opening and the second opening using a first process; and
depositing a conductive material over the barrier layer in the first opening and the second opening using a second process.

4. The method of claim 3, wherein the first TSV has a first width, the first conductive pad has a second width, and the second width is greater than the first width.

5. The method of claim 1, further comprising:
planarizing a second surface of the semiconductor substrate to expose the first TSV, the second surface being on a second side of the semiconductor substrate, the second side being on an opposite side of the semiconductor substrate as the first side.

6. The method of claim 5, further comprising:
forming a first bonding layer over the exposed first TSV and on the second side of the semiconductor substrate;
forming a first bonding pad in the first bonding layer; and
bonding a first semiconductor die to the first wafer, wherein the bonding comprises:
bonding the first bonding layer to a second bonding layer of the first semiconductor die using direct oxide-to-oxide bonding; and
bonding the first bonding pad to a second bonding pad of the first semiconductor die using direct metal-to-metal bonding, wherein the first bonding pad is in physical contact with the first TSV.

7. The method of claim 1, wherein forming the first wafer further comprises:
forming a guard ring structure in the plurality of first dielectric layers, wherein the guard ring structure surrounds the first TSV and is in physical contact with the first conductive pad.

8. A method of manufacturing a semiconductor device, the method comprising:
forming a first wafer, the first wafer comprising a first interconnect structure over a semiconductor substrate, wherein forming the first wafer comprises:
forming a plurality of first dielectric layers over the semiconductor substrate;
depositing a second dielectric layer over the plurality of first dielectric layers;
forming a first opening that extends through the second dielectric layer, the plurality of first dielectric layers, and partially through the semiconductor substrate;
depositing a dielectric liner over the second dielectric layer and on a bottom surface and sidewalls in the first opening;
etching portions of the dielectric liner and the second dielectric layer to form a second opening, wherein the second opening overlaps a remaining portion of the first opening; and
concurrently forming a first through substrate via (TSV) in the remaining portion of the first opening and a first conductive pad in the second opening.

9. The method of claim 8, wherein forming the first wafer further comprises:
filling the first opening with a first Bottom Anti-Reflective Coating (BARC) layer; and
etching a top portion of the first BARC layer, wherein after etching the top portion of the first BARC layer, and after etching the portions of the dielectric liner and the second dielectric layer to form the second opening, a topmost surface of a remaining portion of the first BARC layer in the remaining portion of the first opening is level with a bottom surface of the second opening.

10. The method of claim 9, wherein concurrently forming the first TSV in the remaining portion of the first opening and the first conductive pad in the second opening comprises:
removing the remaining portion of the first BARC layer in the remaining portion of the first opening; and
depositing a conductive material in the second opening and the remaining portion of the first opening.

11. The method of claim 8, wherein the first TSV has a first width, the first conductive pad has a second width, and the second width is greater than the first width.

12. The method of claim 8, wherein forming the first wafer further comprises:
forming a contact pad in the plurality of first dielectric layers;
forming a third opening that extends through the second dielectric layer and the dielectric liner; and
during concurrently forming the first TSV in the remaining portion of the first opening and the first conductive pad in the second opening, forming a second conductive pad in the third opening, the second conductive pad being electrically connected to the contact pad in the plurality of first dielectric layers.

13. The method of claim 8, further comprising:
bonding a first semiconductor die to the first wafer, wherein the bonding comprises:
bonding a first bonding layer of the first semiconductor die to the dielectric liner using direct oxide-to-oxide bonding; and
bonding a first bonding pad of the first semiconductor die to the first conductive pad using direct metal-to-metal bonding.

14. The method of claim 13, further comprising:
forming a guard ring structure in the plurality of first dielectric layers, wherein the guard ring structure surrounds the first TSV, and wherein the guard ring structure is electrically connected to the first conductive pad.

15. A package comprising:
a first die comprising a first interconnect structure on a first side of a first semiconductor substrate, the first interconnect structure comprising:
a plurality of first dielectric layers;
a second dielectric layer over the plurality of first dielectric layers; and
a dielectric liner over the second dielectric layer, wherein a first conductive pad is disposed to extend through the dielectric liner and the second dielectric layer, and a first through substrate via (TSV) is disposed to extend through the plurality of first dielectric layers and the first semiconductor substrate, wherein the dielectric liner is also disposed on sidewalls of the first TSV, and wherein the first TSV and the first conductive pad are in physical contact;
a second die over and bonded to the first die, the second die comprising:
a first bonding layer over a second semiconductor substrate; and
a first bonding pad disposed in the first bonding layer, wherein a bond between the first bonding layer of the second die and the dielectric liner is an oxide-to-oxide bond, and a bond between the first bonding pad of the second die and the first conductive pad is a metal-to-metal bond.

16. The package of claim 15, wherein the first conductive pad is disposed over the first TSV, wherein each of the first TSV and the first conductive pad comprise:
a conductive material; and
a barrier layer on sidewalls of the conductive material, wherein the barrier layer is not disposed between the conductive material of the first TSV and the conductive material of the first conductive pad, and wherein the barrier layer is disposed on a portion of a bottom surface of the conductive material of the first conductive pad.

17. The package of claim 16, wherein a first width of the first conductive pad is greater than a second width of the first TSV.

18. The package of claim 15, further comprising a package substrate coupled to a second side of the first semiconductor substrate using conductive connectors, wherein the second side is on an opposite side of the first semiconductor substrate as the first side.

19. The package of claim 15, wherein a material of the dielectric liner and a material of the second dielectric layer are different.

20. The package of claim 15, further comprising a guard ring structure disposed in the plurality of first dielectric layers, wherein the guard ring structure surrounds the first TSV, and wherein the guard ring structure is electrically coupled to the first conductive pad.
